(19) United States
(12) Patent Application Publication
(10) Pub. No.: US 2019/0010844 A1
(43) Pub. Date: Jan. 10, 2019

(54) COOLING APPARATUS, EXHAUST GAS PURIFICATION APPARATUS, AND VEHICLE

(71) Applicant: FUJITSU LIMITED, Kawasaki-shi (JP)

(72) Inventors: Teru Nakanishi, Isehara (JP); Tatsuya Hirose, Yokohama (JP)

(73) Assignee: FUJITSU LIMITED, Kawasaki-shi (JP)

(21) Appl. No.: 16/025,011

(22) Filed: Jul. 2, 2018

(30) Foreign Application Priority Data
Jul. 7, 2017 (JP) 2017-133877

(51) Int. Cl. F01N 3/04; H01L 23/473; B60H 1/32; F01N 3/021

(52) U.S. Cl. CPC F01N 3/04; H01L 23/473; B60H 1/00271; F01N 3/021; B60H 1/3233

(57) ABSTRACT

A cooling apparatus includes a heat sink including a plurality of fins on one surface of a base portion, and a coolant supply unit configured to supply a coolant to the fins of the heat sink, wherein a water-repellent area and a hydrophilic area are formed on a surface of each of the fins, and the hydrophilic area is formed on a base portion side of each of the fins and the water-repellent area is formed on a side away from the base portion.

### CROSS-REFERENCE TO RELATED APPLICATIONS

This application is based upon and claims the benefit of priority of the prior Japanese Patent Application No. 2017-133877, filed on Jul. 7, 2017, the entire contents of which are incorporated herein by reference.

### FIELD

The disclosures herein generally relate to a cooling apparatus, an exhaust gas purification apparatus, and a vehicle.

### BACKGROUND

It is generally known that an apparatus provided with, for example, a semiconductor device generates heat when in operation. When such an apparatus or a semiconductor device generates heat, resulting in an elevated temperature, a malfunction or a failure may occur in the semiconductor device and the like. In order to suppress a temperature rise, a cooling apparatus is installed. As such a cooling apparatus, various types of cooling apparatuses are available.

### RELATED-ART DOCUMENTS

### Patent Document

[Patent Document 1] Japanese Laid-open Patent Publication No. 60-124956

[Patent Document 2] Japanese Laid-open Patent Publication No. 7-283034

[Patent Document 3] Japanese Laid-open Patent Publication No. 2013-64578

[Patent Document 4] Japanese Laid-open Patent Publication No. 9-283678

[Patent Document 5] Japanese Laid-open Patent Publication No. 2010-91146

[Patent Document 6] Japanese Laid-open Patent Publication No. 2007-115810

### SUMMARY

According to an aspect of the embodiment, a cooling apparatus includes a heat sink including a plurality of fins on one surface of a base portion, and a coolant supply unit configured to supply a coolant to the fins of the heat sink, wherein a water-repellent area and a hydrophilic area are formed on a surface of each of the fins, and the hydrophilic area is formed on a base portion side of each of the fins and the water-repellent area is formed on a side away from the base portion.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a structural drawing illustrating a cooling apparatus and an exhaust gas purification apparatus according to a first embodiment;

FIG. 2 is a structural drawing illustrating a heat sink according to the first embodiment;

FIG. 3 is a drawing for explaining a heat sink used for comparison;

FIG. 4 is a drawing for explaining a heat sink used for comparison;

FIG. 5 is a graph illustrating characteristics of temperature changes when a mist of water is supplied;

FIG. 6 is a flowchart of a cooling method according to the first embodiment;

FIG. 7 is a structural drawing illustrating a heat sink according to a second embodiment;

FIG. 8 is a structural drawing illustrating a heat sink according to a third embodiment;

FIG. 9 is an enlarged view of a main portion of the heat sink according to the third embodiment;

FIG. 10 is a structural drawing illustrating a cooling apparatus and an exhaust gas purification apparatus according to a fourth embodiment;

FIG. 11 is a flowchart of a cooling method according to the fourth embodiment; and

FIG. 12 is a drawing for explaining a vehicle according to a fifth embodiment.

### DESCRIPTION OF EMBODIMENTS

In the following, embodiments of the present invention will be described with reference to the accompanying drawings. The same elements are denoted by the same reference numerals and a duplicate description thereof will be omitted.

### First Embodiment

A cooling apparatus and an exhaust gas purification apparatus according to a first embodiment will be described. The exhaust gas purification apparatus according to the present embodiment includes a diesel particulate filter (DPF) for collecting fine particles such as particulate matter (PM) contained in exhaust gas of a diesel engine and the like. By emitting microwaves generated by a microwave generator, fine particles such as PM accumulated in the DPF are heated and removed, and thereby the DPF can be regenerated. The cooling apparatus according to the present embodiment is used to cool, for example, the microwave generator.

Currently, as an apparatus for collecting fine particles such as PM, an exhaust gas purification apparatus using a DPF has been put to practical use. In such an exhaust gas purification apparatus, fine particles such as PM are accumulated in the DPF by use. Therefore, the DPF needs to be regenerated. As a method for regenerating the DPF, there exists a method for using microwaves emitted by the microwave generator. To be more specific, the microwave generator generates microwaves and the DPF is irradiated with the generated microwaves, such that fine particles such as PM accumulated in the DPF are heated and burned, and thereby the DPF can be regenerated.

The DPF is installed inside an exhaust system of, for example, a bus and a truck with a diesel engine. Also, in order to efficiently irradiate the DPF with microwaves generated by the microwave generator, the microwave generator is disposed near the DPF. However, because regeneration of the DPF is performed by heating and removing fine particles such as PM accumulated in the DPF by using microwaves, the temperature in the vicinity of the DPF tends to become high. Further, the temperature surrounding the microwave generator may sometimes become 100° C. or more. Also, the microwave generator is provided with an amplifier circuit to obtain high-output microwaves, and the temperature of a semiconductor device that forms the amplifier circuit increases when continuous-wave (CW) microwaves are generated.

When the temperature of the semiconductor device increases, the operation of the semiconductor device becomes unstable. As a result, there may be cases where desired microwaves are not stably generated or the lifetime of the semiconductor device becomes short. Further, the semiconductor device itself may be destroyed. Therefore, the microwave generator needs to be cooled. As a simple method of cooling the microwave generator, an air cooling method in which ambient air is supplied for cooling may be conceivable. However, with the air cooling method, it may be difficult to sufficiently cool the microwave generator as the temperature of ambient air becomes high in the middle of summer. Also, as a method with a relatively high cooling capability, a water cooling method may be conceivable. With the water cooling method, piping for water cooling needs to be installed, but the installation of the piping near an exhaust system of a truck or a bus is difficult.

Accordingly, a compact cooling apparatus that can efficiently cool a microwave generator is desired.

### (Cooling Apparatus)

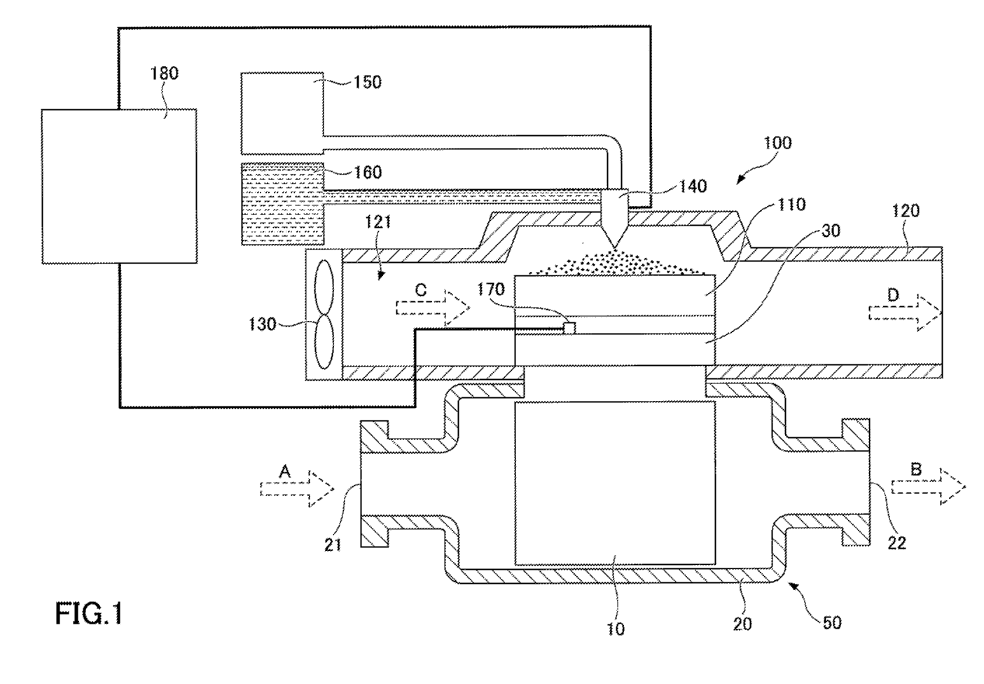

Next, referring to FIG. 1, the cooling apparatus according to the first embodiment will be described. A cooling apparatus 100 according to the present embodiment is attached to an exhaust gas purification apparatus 50 that purifies exhaust gas of a diesel engine. The exhaust gas purification apparatus includes a fine particle collector 10 formed of a DPF or the like in a housing 20, and further includes a microwave generator 30 that generates microwaves. For example, the DPF is formed in a honeycomb structure in which adjacent vent holes are alternately closed, and exhaust gas is discharged from vent holes different from those on the inlet side.

The housing 20 is formed of a metal material such as stainless steel, and covers the periphery of the fine particle collector 10. The housing 20 includes an inlet 21 through which exhaust gas enters and an outlet 22 from which the purified exhaust gas is discharged. In the exhaust gas purification apparatus 50, exhaust gas such as exhaust gas from an engine enters the housing 20 through the inlet 21 in a direction indicated by a broken line arrow A. The exhaust gas that entered the housing 20 passes through the fine particle collector 10 and is purified. The purified exhaust gas is discharged from the outlet 22 in a direction indicated by a broken line arrow B.

The microwave generator 30 can generate electromagnetic waves ranging from 300 MHz to 6 GHz. For example, the microwave generator 30 can generate microwaves of 2.45 GHz. In order to generate high-output microwaves required to heat the fine particle collector 10, the microwave generator 30 uses a semiconductor device formed of a nitride semiconductor. In the exhaust gas purification apparatus 50, by irradiating the fine particle collector 10 with microwaves generated by the microwave generator 30, fine particles such as PM accumulated in the fine particle collector 10 are heated and oxidized, and thereby removed.

When burning and removing fine particles such as PM accumulated in the fine particle collector 10, in order to heat the fine particles such as PM, microwaves are generated and emitted by the microwave generator. As described, the microwave generator 30 is preferably disposed near the fine particle collector 10 such that microwaves generated by the microwave generator 30 are efficiently emitted. When the microwave generator 30 is disposed near the fine particle collector 10 as described above and the fine particle collector 10 is irradiated with microwaves such that fine particles such as PM are removed, the temperature of the fine particle collector 10 becomes high. In this case, the heat may be transferred to the microwave generator 30. Also, when removing the fine particles such as PM, because of operation of the semiconductor device inside the microwave generator 30 to generate the microwaves, heat is generated. Accordingly, heat is applied to the microwave generator 30 from both the inside and the outside.

The cooling apparatus 100 according to the present embodiment includes a heat sink 110, an air duct 120, a fan 130, a coolant injector 140, a compressor 150, a coolant tank 160, a temperature measuring unit 170, a controller 180, and the like.

The heat sink 110 is in contact with the microwave generator 30. The heat sink 110 and the microwave generator 30 are disposed in a space 121 in the air duct 120. A fan 130 is provided on the upstream side of the air duct 120, allowing air to blow in a direction indicated by a broken line arrow C and a broken line arrow D. The coolant injector 140 is a coolant supply unit that supplies a coolant. The coolant injector 140 injects water as a coolant toward the heat sink 110. The compressor 150 that generates compressed air and the coolant tank 160 that stores water as a coolant are coupled to the coolant injector 140. Further, the temperature measuring unit 170 that measures a temperature of the heat sink 110 is provided on the side of the heat sink 110 in contact with the microwave generator 30. The coolant injector 140 and the temperature measuring unit 170 are coupled to the controller 180. In the present embodiment, the compressor 150 and the coolant tank 160 may be coupled to the controller 180. Further, the temperature measuring unit 170 may be provided inside the microwave generator 30 to measure a temperature of the microwave generator 30.

### (Heat Sink)

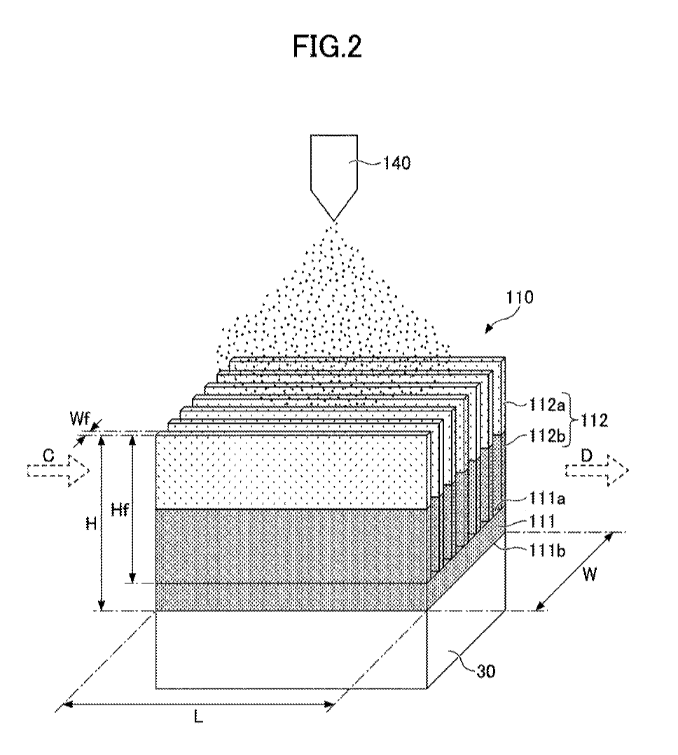

Next, referring to FIG. 2, the heat sink 110 of the cooling apparatus according to the present embodiment will be described. The heat sink 110 includes a base portion 111 and a plurality of fins 112 extending approximately vertically to one surface 111a of the base portion 111. The entire heat sink 110 is formed of a metal material having high thermal conductivity such as aluminum (Al) and copper (Cu). The surface of a water-repellent area 112a of an upper portion of each of the fins 112 is subjected to water-repellent treatment. To be more specific, a fluorine-based resin film is formed on the surface of the water-repellent area 112a or the surface of the water-repellent area 112a is subjected to micromachining so as to repel water. Further, a hydrophilic area 112b of a lower portion of each of the fins 112 of the heat sink 110 and the base portion 111 are subjected to hydrophilic treatment. To be more specific, a titanium oxide film is formed on the surface of the hydrophilic area 112b and on the surface of the base portion 111, or chemical etching such as wet etching or blasting treatment is applied to the surface of the hydrophilic area 112b and the surface of the base portion 111, for example. As used herein, the water-repellent area refers to an area having a water contact angle of 90 degrees or more, and the hydrophilic area refers to an area having a water contact angle of less than 90 degrees.

In the present embodiment, the hydrophilic area 112b is formed on the base portion 111 side of each of the fins 112 of heat sink 110, and the water-repellent area 112a is formed on the side away from the base portion 111.

In the present embodiment, the heat sink 110 is formed of aluminum, and has a width W of 25 mm, a length L of 25 mm, and a height H of 15 mm. The fins 112 each have a height Hf of 13 mm and a thickness Wf of 0.5 mm. The number of the fins 112 illustrated in FIG. 2 is seven, but the number of the fins is not limited thereto. In the present embodiment, the fluorine-based resin film having a thickness of 5 μm is formed on the surface of the water-repellent area 112a of the upper portion of the each of the fins 112 of the heat sink 110. Also, the water-repellent area 112a has a water contact angle of approximately 110 degrees. Further, blasting treatment using fine particles of alumina is applied to the hydrophilic area 112b of the lower portion of each of the fins 112 of the heat sink 110 and to the base portion 111. The hydrophilic area 112b and the base portion 111 each have a water contact angle of approximately 70 degrees to 80 degrees. As fine particles used in blasting treatment, in addition to fine particles of alumina, fine particles of silicon oxide, ice, and dry ice may be used.

The heat sink 110 is disposed on the microwave generator 30. The other surface 111b of the base portion 111 of the heat sink 110 is in contact with the microwave generator 30. Accordingly, the fins 112 of the heat sink 110 allow heat generated in the microwave generator 30 to be dissipated.

### (Cooling)

In the present embodiment, the coolant injector 140 that injects water as a coolant is disposed above the fins 112 of the heat sink 110. Therefore, the coolant injector 140 can inject water toward the fins 112 of the heat sink 110. The direction in which gravity acts is a direction from up to down. In the heat sink 110, each of the fins 112 has the water-repellent area 112a at its upper portion and the hydrophilic area 112b at its lower portion. Therefore, the direction in which gravity acts is a direction from the water-repellent area 112a toward the hydrophilic area 112b. As used herein, the coolant injector 140 may be referred to as a coolant supply unit.

In the present embodiment, the coolant injector 140 entirely sprays a mist of water having a particle size of 100 μm to 200 μm toward the fins 112 of the heat sink 110. To be more specific, the water is supplied from the upper side, which is the opposite side of the heat sink 110 from the base portion 111 side, toward the fins 112. Further, the water supplied may be in the form of droplets, and is preferably in the form of a mist in terms of adhesion to the fins 112.

The mist of water sprayed from the coolant injector 140 toward the fins 112 of the heat sink 110 adheres to the water-repellent area 112a that is the upper portion of the fins 112. However, as the water-repellent area 112a has been subjected to water-repellent treatment, the water is repelled and flows downward by gravity. Under the water-repellent area 112a of the upper portion of the fins 112 of the heat sink 110, the hydrophilic area 112b that is the lower portion of each of the fins 112 is formed. Therefore, the water repelled by the water-repellent area 112a that is the upper portion of the fins 112 flows down to the hydrophilic area 112b that is the lower portion of the fins 112. The hydrophilic area 112b that is the lower portion of each of the fins 112 and the base portion 111 have been subjected to hydrophilic treatment. Thus, the water adhering to the surfaces wets and spreads on the surfaces, causing thin water films to be formed.

In the present embodiment, because the thin water films are formed on the surface of the hydrophilic area 112b that is the lower portion of each of the fins 112 and on the surface of the base portion 111, the water can be efficiently vaporized. Therefore, the heat of the heat sink 110 can be efficiently removed. Accordingly, it is possible to efficiently cool both the heat sink 110 and the microwave generator 30 in contact with the heat sink 110.

Further, in the present embodiment, the microwave generator 30 and the heat sink 110 are disposed in the space 121 in the air duct 120. On the upstream side of the space 121, the fan 130 is provided. As the fan 130 provided on the upstream side of the space 121 rotates, the air blows in the space 121 in the air duct 120. The horizontal direction of each of the fins 112 extends along a direction in which the air blows, and thus, the air passes through between the fins 112. The fan 130 is adjusted such that the air speed in the space 121 in the air duct 120 becomes 5 m/s. As the air blows near the hydrophilic area 112b of each of the fins 112 of the heat sink 110 where the water wets and spreads on the surface, the water can be efficiently vaporized. Accordingly, the microwave generator 30 in contact with the heat sink 110 can be efficiently cooled.

### (Cooling Experiment)

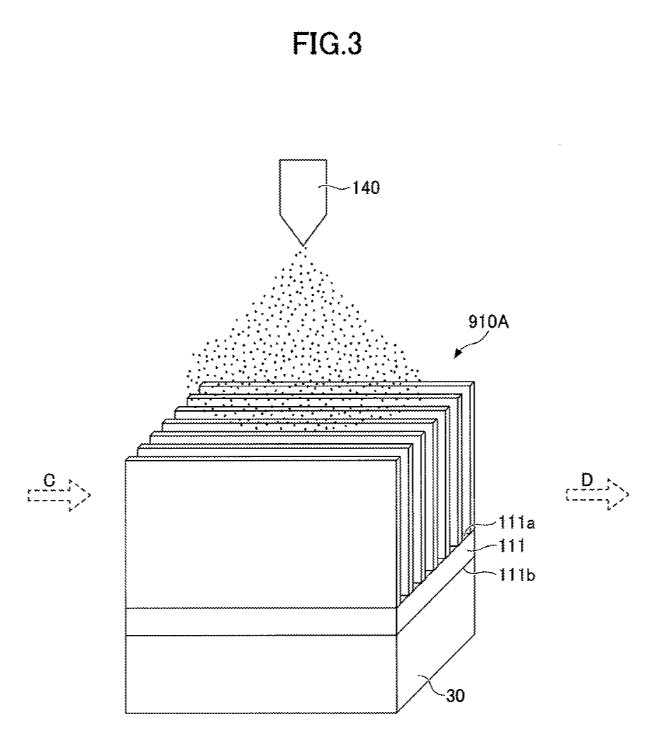

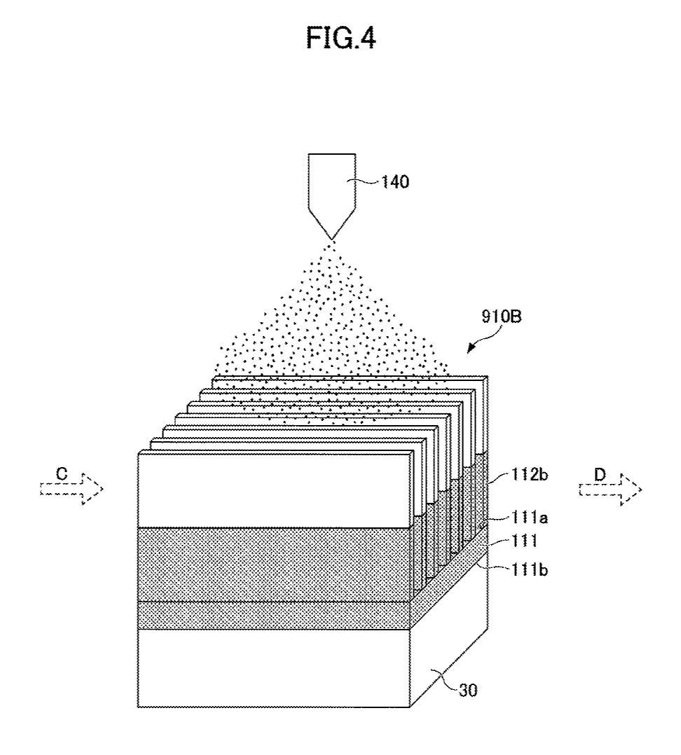

Next, an experiment was performed on a cooling effect of the heat sink of the cooling apparatus according to the present embodiment. To be more specific, a mist of water was injected from the above-described coolant injector 140 toward the heat sink 110 of the present embodiment illustrated in FIG. 2, and a temperature of the heat sink was measured. For comparison, a similar experiment was performed on a heat sink 910A having neither a water-repellent area nor a hydrophilic area illustrated in FIG. 3 and on a heat sink 910B having a hydrophilic area 112b and not having a water-repellent area illustrated in FIG. 4, and temperatures of the heat sinks were measured. Further, water supplied from the coolant injector 140 was a mist of water having a particle size of 100 μm to 200 μm. The speed of air blowing near the heat sink was 5 m/s. External shapes of the heat sink 910A and the heat sink 910B and sizes of fins were approximately the same as those of the heat sink 110 of the cooling apparatus according to the present embodiment.

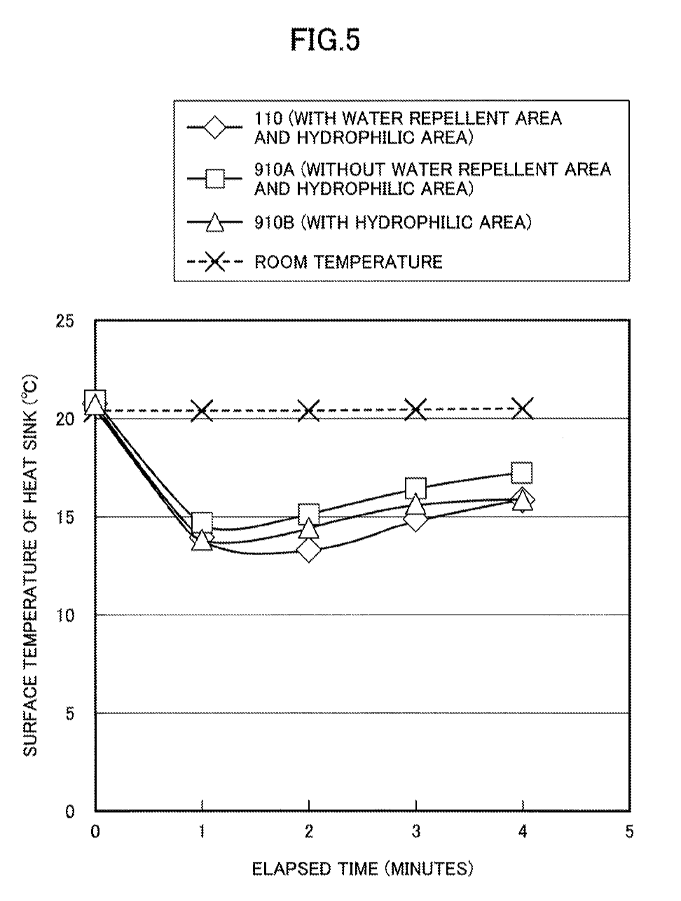

FIG. 5 illustrates the results. As illustrated in FIG. 5, the heat sink 110 according to the present embodiment and the heat sink 910B illustrated in FIG. 4 have lower temperatures than that of the heat sink 910A having neither the water-repellent area nor the hydrophilic area, and thus are efficient in terms of cooling. In the heat sink 910A illustrated in FIG. 3, each of the fins does not have a hydrophilic area. Therefore, even if water adheres to each of the fins, the water does not wet or spread on the surface. As a result, water droplets are formed and flow downward, causing cooling to be inefficient.

Also, as illustrated in FIG. 5, the heat sink 110 according to the present embodiment has an even lower temperature than that of the heat sink 910B having the hydrophilic area 112b. This is assumed to be because, by providing the water-repellent area 112a, which repels water adhering thereto, the water can be efficiently collected onto the hydrophilic area 112b that is closer to the microwave generator 30 that generates heat. Accordingly, a heat sink having both a water-repellent area and a hydrophilic area is more efficient in terms of cooling than a heat sink having a hydrophilic area only. Further, in FIG. 5, after the elapse of 1 to 2 minutes, the temperatures rise again. This is assumed to be because the water adhering to the fins of each of the heat sinks was vaporized. Accordingly, it is preferable to supply water to the heat sink at predetermined intervals, by taking a vaporization time into account.

### (Cooling Method)

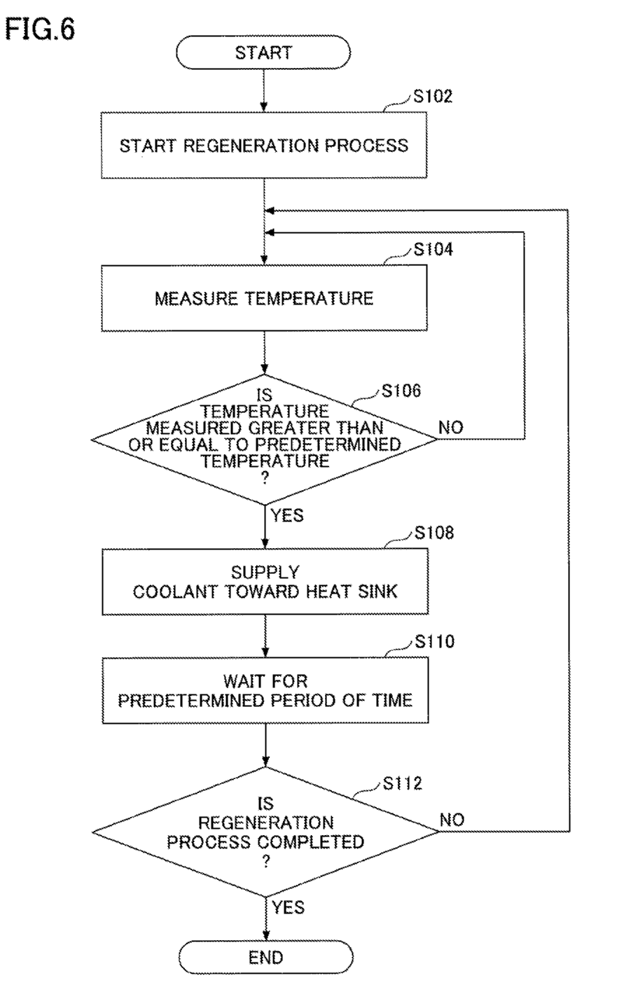

Next, referring to FIG. 6, a cooling method using the cooling apparatus according to the present embodiment will be described. The cooling method according to the present embodiment is controlled and performed by the controller 180. Further, based on a temperature measured by the temperature measuring unit 170, the controller 180 controls the coolant injector 140 or controls the compressor 150 and the coolant tank 160. In the present embodiment, the fan 130 may start rotating in accordance with the start of a regeneration process or may be rotating at all times. The speed of the air produced by the fan 130 is approximately 5 m/s.

First, in step 102 (S102), a process of regenerating the DPF, which is the fine particle collector 10, is started. Specifically, the process of regenerating the fine particle collector 10 is started when an amount of fine particles such as PM accumulated in the fine particle collector 10 exceeds a predetermined value. The process of regenerating the fine particle collector 10 is performed by irradiating the fine particle collector 10 with microwaves generated by the microwave generator 30 so as to heat the fine particle collector 10. As the temperature of the fine particle collector 10 increases, heat is transferred to the microwave generator 30 disposed near the fine particle collector 10. Further, the semiconductor device of the microwave generator 30 also generates heat when generating microwaves, causing the temperature of the microwave generator 30 to increase.

Next, in step 104 (S104), the temperature measuring unit 170 measures a temperature. The temperature measuring unit 170 may be attached to the heat sink 110 as illustrated in FIG. 1, or may be provided in the microwave generator 30. It is preferable to provide the temperature measuring unit 170 in the microwave generator 30 because a temperature can be more accurately measured.

Next, in step 106 (S106), it is determined whether the temperature measured in step 104 is greater than or equal to a predetermined temperature. To be more specific, it is determined whether the temperature measured in step 104 is greater than or equal to 50° C. When the temperature measured in step 104 is greater than or equal to the predetermined temperature, the process proceeds to step 108. When the temperature measured is less than the predetermined temperature, the process returns to step 104 and a temperature is measured again.

Next, in step 108 (S108), water is supplied toward the heat sink 110. To be more specific, a mist of water is injected from the coolant injector 140 toward the heat sink 110 for 5 seconds, for example. As a result, the mist of water adhering to the surface of the water-repellent area 112a of each of the fins 112 of the heat sink 110 flows down to the hydrophilic area 112b. Accordingly, the mist of water wets and spreads on the surface of the hydrophilic area 112b. Further, in the present embodiment, instead of controlling the coolant injector 140, by controlling the compressor 150 and the coolant tank 160, the mist of water may be injected from the coolant injector 140 toward the heat sink 110.

Next, in step 110 (S110), the controller 180 waits for a predetermined period of time. For example, the controller 180 waits for the elapse of approximately 1 minute. After the coolant injector 140 injects the mist of water toward the heat sink 110, it takes time for the mist of water to wet and spread on the surface of the hydrophilic area 112b of each of the fins 112. Further, because water has low thermal conductivity, it also takes time for the water to be vaporized and the temperature to decrease. Accordingly, the controller 180 waits for the predetermined period of time.

Next, in step 112 (S112), it is determined whether the process of regenerating the DPF, which is the fine particle collector 10, is completed. To be more specific, the process of regenerating the fine particle collector 10 is performed by irradiating the fine particle collector 10 with microwaves generated by the microwave generator 30 for approximately 30 minutes. Therefore, the completion of the process of regenerating the fine particle collector 10 may be determined based on whether 30 minutes has elapsed after the start of the process in step 102. When the process of regenerating the fine particle collector 10 is completed, the process ends. When the process of regenerating the fine particle collector 10 is not completed, the process returns to step 104. Further, when the process of regenerating the fine particle collector 10 is completed, the microwave generator 30 also stops generating microwaves.

### Second Embodiment

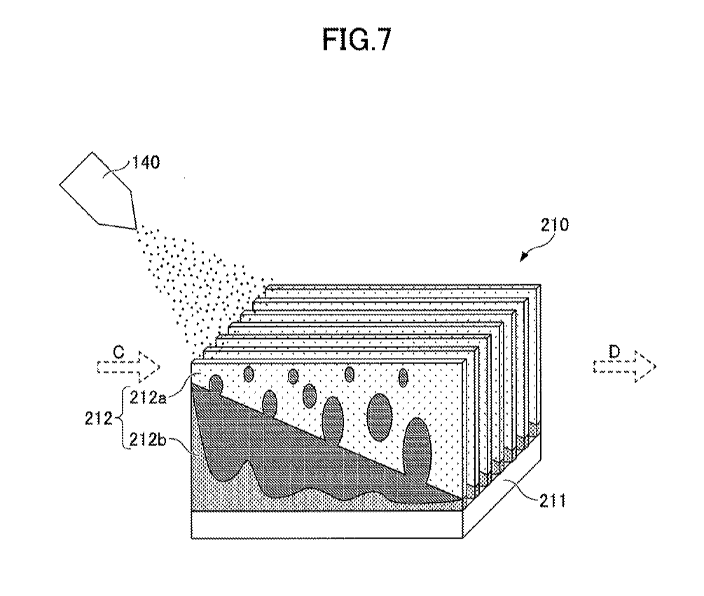

Next, a second embodiment will be described. In the second embodiment, as illustrated in FIG. 7, a hydrophilic area 212b is formed to be wider on an upstream side of fins 212 of a heat sink 210 than on a downstream side, and a water-repellent area 212a is formed to be narrower on the upstream side than on the downstream side. Further, the coolant injector 140 is provided on the upstream side of the heat sink 210. A mist of water is supplied from the upstream side toward the heat sink 210 in an oblique direction. On the upstream side of the fins 212 of the heat sink 210, the hydrophilic area 212b extends to an upper side. Therefore, air blowing by the upper side allows the water wetting and spreading on the hydrophilic area 212b to be vaporized and the heat to be removed. Further, on the downstream of the fins 212 of the heat sink 210, the hydrophilic area 212b is formed on a lower side, air blowing by the lower side causes the water wetting and spreading on the hydrophilic area 212b to be vaporized and heat to be removed. With respect to the air blowing in the air duct 120 is air, water will not be vaporized when the saturation vapor pressure of the air is exceeded. Therefore, in the present embodiment, on the upstream side of the fins 212 of the heat sink 210, the water is vaporized by the air blowing by the upper side, and on the downstream side of the fins 212 of the heat sink 210, the water is vaporized by the air blowing by the lower side. Accordingly, the water is efficiently vaporized. Also, the temperature of the microwave generator 30 can be efficiently reduced.

Details other than the above are similar to those of the first embodiment.

### Third Embodiment

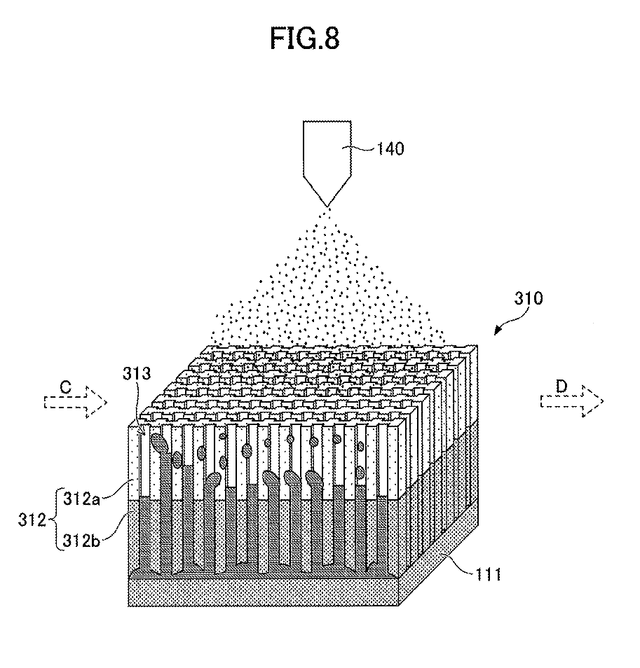

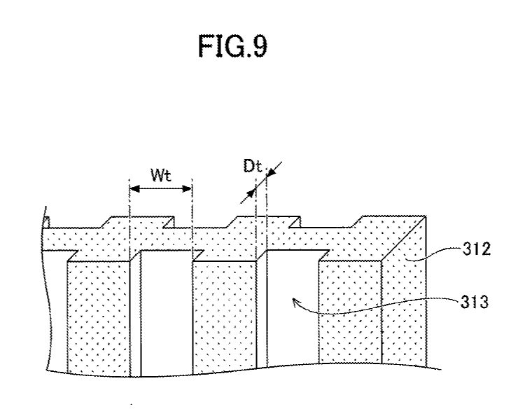

Next, a third embodiment will be described. In the present embodiment, as illustrated in FIG. 8 and FIG. 9, grooves 313 extending along a top-bottom direction are provided on the surface of each of fins 312 of the heat sink 310. FIG. 8 is a perspective view of the heat sink 310 according to the present embodiment. FIG. 9 is a partially enlarged view of one of the fins 312 of the heat sink 310.

When the coolant injector 140 injects a mist of water toward the heat sink, the mist of water adheres to the surface of a water-repellent area of each of the fins, but is repelled by the water-repellent area of each of the fins. Thus, there may be a case where water droplets may be blown and carried away from the fins by air coming from a direction indicated by a broken line arrow C. The water droplets blown and carried away from the fins do not contribute to cooling the heat sink.

In light of the above, in the present embodiment, the grooves 313 extending in the top-bottom direction are provided on each of the fins 312. Even when water droplets adhering to a water-repellent area 312a are blown by air, the water droplets can enter the grooves 313. The water droplets entering the grooves 313 flow in a downward direction from the water-repellent area 312a toward a hydrophilic area 312 and wet and spread on the hydrophilic area 312b. Accordingly, the water adhering to the fins 312 of the heat sink 310 can be efficiently used for cooling. In the present embodiment, the grooves 313 formed on the fins 312 each have a width Wt of 0.1 mm and a depth Dt of a 0.1 mm. Also, the insides of the grooves 313 may be subjected to hydrophilic treatment.

Details other than the above are similar to those of the first embodiment.

### Fourth Embodiment

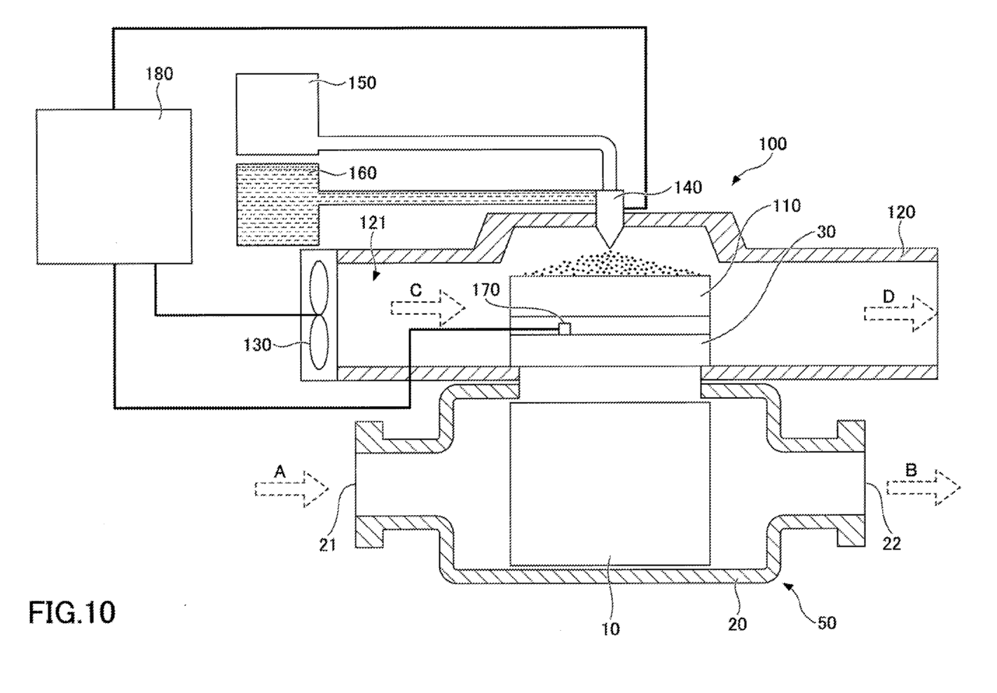

Next, a cooling apparatus according to a fourth embodiment will be described. In the cooling apparatus according to the present embodiment, as illustrated in FIG. 10, the fan 130 is configured to be coupled to the controller 180, and the fan 130 and the coolant injector 140 are controlled based on a temperature measured by the temperature measuring unit 170. In a case where water droplets as a coolant are supplied from the coolant injector 140 toward the heat sink 110 under a strong air current blowing near the heat sink 110, the water droplets are blown away by the air before or after adhering to the heat sink 110. Therefore, in the present embodiment, while water droplets are supplied from the coolant injector 140 toward the heat sink 110, the number of rotations of the fan 130 is decreased or the rotation is stopped so as to prevent the water droplets from being blown away by the air.

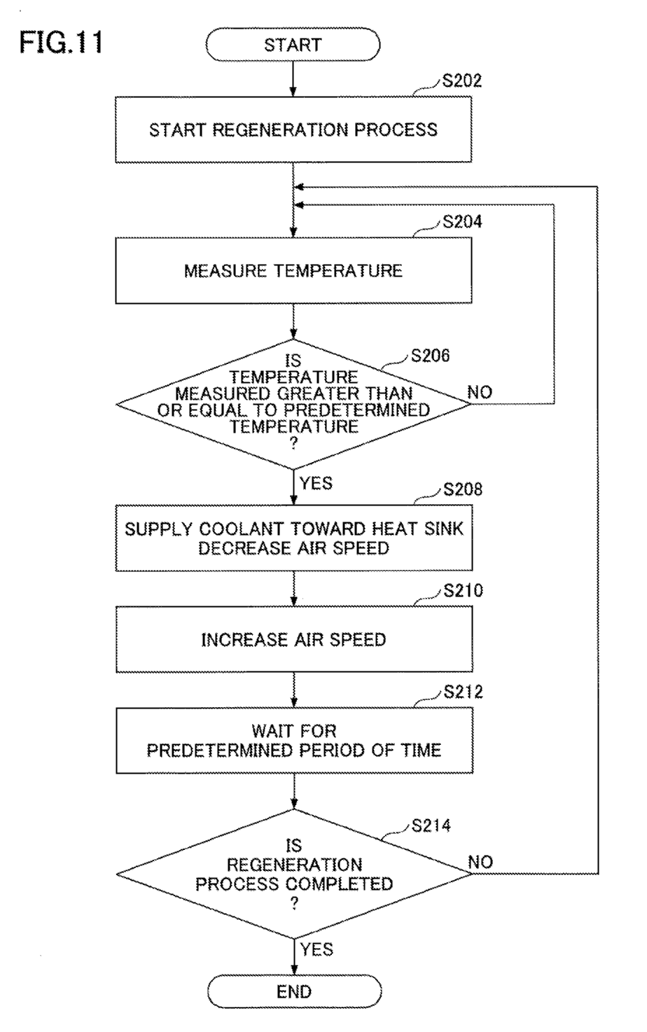

Next, referring to FIG. 11, a cooling method using the cooling apparatus according to the present embodiment will be described. The cooling method according to the present embodiment is controlled and performed by the controller 180. Further, the fan 130, the coolant injector 140, and the like are controlled based on a temperature measured by the temperature measuring unit 170.

First, in step 202 (S202), a process of regenerating the DPF, which is the fine particle collector 10, is started. Accordingly, the temperature of the microwave generator 30 increases.

Next, in step 204 (S204), the temperature measuring unit 170 measures a temperature.

Next, in step 206 (S206), it is determined whether the temperature measured in step 204 is greater than or equal to a predetermined temperature. To be more specific, it is determined whether the temperature measured in step 204 is greater than or equal to 50° C. When the temperature measured in step 204 is greater than or equal to the predetermined temperature, the process proceeds to step 208. When the temperature measured is less than the predetermined temperature, the process returns to step 204 and a temperature is measured again.

Next, in step 208 (S208), water as a coolant is supplied toward the heat sink 110. At this time, when the fan 130 is rotating, the number of rotations of the fan 130 is decreased or the rotation is stopped so as to decrease the air speed. The air speed is, for example, less than or equal to 1 m/s. To be more specific, a mist of water is injected from the coolant injector 140 toward the heat sink 110 for 5 seconds, for example. During the time, the number of rotations of the fan 130 is decreased or the rotation is stopped so as to decrease the air speed. Accordingly, the mist of water can efficiently adhere to the fins 112 of the heat sink 110 without being blown away, and can wet and spread on the surface of the hydrophilic area 112b.

Next, in step 210 (S210), after the supply of the mist of water as the coolant toward the heat sink 110 is completed, the air speed is increased by increasing the number of rotations of the fan 130 or by starting the rotation of the fan 130 if the fan 130 is stopped. The air speed is approximately 5 m/s.

Next, in step 212 (S212), the controller 180 waits for a predetermined period of time. For example, the controller 180 waits for the elapse of approximately 1 minute.

Next, in step 214 (S214), it is determined whether the process of regenerating the DPF, which is the fine particle collector 10, is completed. To be more specific, when the process of regenerating the fine particle collector 10 is completed, the process ends. When the process of regenerating the fine particle collector 10 is not completed, the process returns to step 204.

Details other than the above are similar to those of the first embodiment. As the heat sink according to the present embodiment, the heat sink according to the second embodiment or according to the third embodiment may also be used. Further, in the present embodiment, the controller 180 may control the compressor 150 and the coolant tank 160, instead of controlling the coolant injector 140.

### Fifth Embodiment

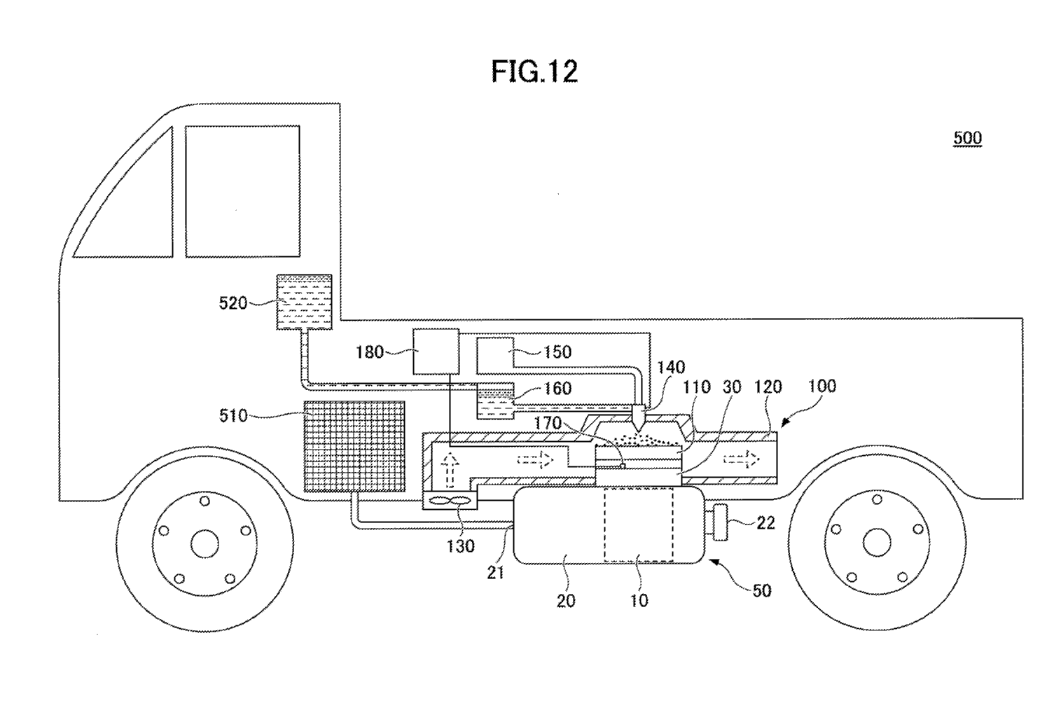

Next, a fifth embodiment will be described. The present embodiment describes a vehicle in which the cooling apparatus and the exhaust gas purification apparatus of the first embodiment are mounted. The vehicle according to the present embodiment will be described with reference to FIG. 12.

A vehicle 500 according to the present embodiment includes the cooling apparatus 100 and the exhaust gas purification apparatus 50 of the first embodiment and also includes an engine 510 such as a diesel engine and an air conditioner 520.

In the vehicle 500 according to the present embodiment, an exhaust port of the engine 510 is coupled to the inlet 21 of the housing 20 of the exhaust gas purification apparatus 50. Exhaust gas from the engine 510 is purified in the fine particle collector 10 of the exhaust gas purification apparatus 50 and is discharged from the outlet 22 of the housing 20. Further, water as a coolant needs to be stored in the coolant tank 160. The coolant tank 160 may be filled with water at a time when fuel is supplied to the vehicle.

The air conditioner 520 is installed in the vehicle 500. During a hot summer season, in order to maintain comfort, the air conditioner 520 may be utilized to air-condition the inside of the vehicle where the driver is seated. When the air conditioner 520 is utilized for air conditioning, water is produced. The water produced by the air conditioner 520 can be stored in the coolant tank 160 and supplied to the heat sink 110 of the cooling apparatus, such that the water produced by the air conditioner 520 for air conditioning can be effectively utilized.

Further, the vehicle according to the present embodiment may also use any of the cooling apparatuses according to the second to fourth embodiments.

According to at least one embodiment, a cooling apparatus that is compact and enables efficient cooling can be provided.

Although the embodiments have been specifically described above, the present invention is not limited to the specific embodiments and various modifications and variations may be made without departing from the scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention have been described in detail, it should be understood that the various changes, substitutions, and alterations could be made hereto without departing from the spirit and scope of the invention.

What is claimed is:

1. A cooling apparatus comprising:
a heat sink including a plurality of fins on one surface of a base portion; and
a coolant supply unit configured to supply a coolant to the fins of the heat sink,
wherein a water-repellent area and a hydrophilic area are formed on a surface of each of the fins, and
the hydrophilic area is formed on a base portion side of each of the fins and the water-repellent area is formed on a side away from the base portion.

2. The cooling apparatus according to claim 1, comprising a fan configured to blow air toward the heat sink.

3. The cooling apparatus according to claim 2, wherein the hydrophilic area of each of the fins is formed to be wider on an upstream side of the air than on a downstream side, and the water-repellent area of each of the fins is formed to be narrower on the upstream side of the air than on the downstream side.

4. The cooling apparatus according to claim 1, wherein one or more grooves extending from the water-repellent area toward the hydrophilic area are provided on each of the fins.

5. The cooling apparatus according to claim 1, wherein the heat sink is configured to be disposed such that a direction from the water-repellent area toward the hydrophilic area becomes a direction in which gravity acts.

6. The cooling apparatus according to claim 1, wherein the coolant supplied from the coolant supply unit is in a droplet form or in a mist form.

7. The cooling apparatus according to claim 1, wherein a resin film including fluorine is formed on a surface of the water-repellent area of each of the fins.

8. The cooling apparatus according to claim 1, wherein a titanium oxide film is formed on a surface of the hydrophilic area of each of the fins, or chemical etching treatment or blasting treatment is applied to the surface of the hydrophilic area of each of the fins.

9. The cooling apparatus according to claim 1, wherein another surface of the base portion of the heat sink is in contact with a heat generating member so as to cool the heat generating member, the cooling apparatus comprising,
a temperature measuring unit configured to measure a temperature of the heat sink or the heat generating member.

10. The cooling apparatus according to claim 9, comprising a controller configured to control supply of the coolant from the coolant supply unit based on the temperature measured by the temperature measuring unit.

11. The cooling apparatus according to claim 10, wherein the controller is configured to start the supply of the coolant from the coolant supply unit in response to the temperature measured by the temperature measuring unit becoming greater than or equal to a predetermined temperature.

12. The cooling apparatus according to claim 1, wherein the coolant is water.

13. An exhaust gas purification apparatus comprising:
the cooling apparatus according to claim 1;
a fine particle collector configured to collect fine particles included in exhaust gas; and
a microwave generator configured to generate microwaves emitted to the fine particle collector;
wherein another surface of the base portion of the heat sink is in contact with the microwave generator.

14. The exhaust gas purification apparatus according to claim 13, wherein the coolant is water.

15. A vehicle comprising:
the exhaust gas purification apparatus according to claim 14; and
an air conditioner,
wherein the air conditioner is coupled to a coolant tank that stores water produced during air conditioning by the air conditioner, and
the water stored in the coolant tank is used as the coolant supplied from the coolant supply unit.
